(19) United States
(12) Patent Application Publication
(10) Pub. No.: US 2008/0229264 A1
(43) Pub. Date: Sep. 18, 2008

(54) Semiconductor evaluation apparatus, semiconductor evaluation method and semiconductor evaluation program

(75) Inventor: Yukio Okuda, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/071,856

(22) Filed: Feb. 27, 2008

(30) Foreign Application Priority Data
Mar. 16, 2007 (JP) 2007-067930

(51) Int. Cl. G06F 17/50; G06F 9/45; G01R 31/02

(52) U.S. Cl. 716/6; 324/763

(57) ABSTRACT

The present invention provides a semiconductor evaluation apparatus. The semiconductor evaluation apparatus includes: a first integrated circuit; a second integrated circuit; a test section; a measurement section; and a computation section for determining whether a device is good or defective based on sets of power supply voltage and clock period.

### CROSS REFERENCES TO RELATED APPLICATIONS

The present invention contains subject matter related to Japanese Patent Application JP 2007-067930 filed in the Japan Patent Office on Mar. 16, 2007, the entire contents of which being incorporated herein by reference.

### BACKGROUND OF THE INVENTION

1. Field of the Invention

The present invention relates to a semiconductor evaluation apparatus for evaluating the performance of a semiconductor, a semiconductor evaluation method typically adopted by the semiconductor evaluation apparatus and a semiconductor evaluation program implementing the semiconductor evaluation method.

2. Description of the Related Art

With the progress in miniaturization of semiconductors, the number of variations between processes has been increasing, raising a problem of parametric defects caused by the variations.

A parametric defect is a defect that can be detected by applying an operating condition such as a power-supply voltage, a temperature and/or an operating frequency to the product. It is necessary to detect a product with a parametric defect and to identify the cause of the defect. However, there is no effective technique for detecting a product with a parametric defect and identifying the cause of the defect.

As a method for obtaining the parametric performance of an LSI, there is known a Shmoo technique for determining whether a LSI is a good LSI capable of executing its functions or a defective LSI incapable of executing the functions in a test carried out on the LSI by varying the power-supply voltage applied to the LSI and the operating frequency of the LSI and then for plotting a combination of conditions for a good LSI. Since there is no theoretical analysis method for the Shmoo technique, however, the technique is mainly applied to analyses of LSI defects. For more information, the reader is suggested to refer to documents such as the following non-patent reference:

M. Burns and G. W. Roberts, “An Introduction to Mixed-Signal IC Test and Measurement,” New York 10016: Oxford University Press, 2001.

### SUMMARY OF THE INVENTION

In order to recognize fabrication variations generated in processes to fabricate semiconductors, a monitor circuit is provided in the periphery or inside of a dedicated or production LSI as a circuit for monitoring the performance of the LSI.

Since the minimum dimensions of a device are smaller than the wavelength of light generated by a light source in a lithography process and an absolutely required OPC (Optical Proximity-effect Compensation) causes local errors, however, a correlation with a value generated by the monitor circuit cannot be established. Thus, it becomes necessary to directly monitor the performance of the circuit of a product.

Inventors of the present invention have innovated a semiconductor evaluation apparatus capable of acquiring information on an internal delay in an LSI, carrying out process monitoring, carrying out a defect analysis and determining whether the LSI is good or defective without making use of any special circuit employed by the LSI, innovated a semiconductor evaluation method typically to be adopted by the semiconductor evaluation apparatus and innovated a semiconductor evaluation program implementing the semiconductor evaluation method.

In accordance with a first embodiment of the present invention, there is provided a semiconductor evaluation apparatus including:

a first integrated circuit to be determined as a good or defective circuit in accordance with a combination of a power-supply voltage V_{DD} and a clock frequency;

a second integrated circuit serving as a source for providing information on an operation speed varying in accordance with the power-supply voltage V_{DD};

a test section for producing at least two sets of (V_{DD}, t_{PD}) where the notation V_{DD} denotes a specific power-supply voltage V_{DD} peculiar to the first integrated circuit whereas the notation t_{PD} denotes a clock period t_{PD} which is the reciprocal of a maximum clock frequency giving a determination result indicating that the first integrated circuit is a good circuit at the specific power-supply voltage V_{DD};

a measurement section for producing at least 2 sets of (V_{DD}, t_{PD}) where the notation V_{DD} denotes a particular power-supply voltage V_{DD} peculiar to the second integrated circuit whereas the notation t_{PD} denotes a clock period t_{PD} obtained as a result of converting the operation speed obtained at the particular power-supply voltage V_{DD}; and

a computation section for computing a clock period t_{PD} at any arbitrary power-supply voltage V_{DD} from first data (V_{DD}1, t_{PD}1) already produced by the test section or the measurement section, a threshold voltage _{VTH} and a coefficient α, which have already been produced by the test section or the measurement section as respectively the threshold voltage and coefficient of a given transistor, as well as a total wiring delay time t_{PWD} already produced by the test section or the measurement section.

In accordance with a second embodiment of the present invention, there is provided a semiconductor evaluation method making use of:

a first integrated circuit to be determined as a good or defective circuit in accordance with a combination of a power-supply voltage V_{DD} and a clock frequency;

a second integrated circuit serving as a source for providing information on an operation speed varying in accordance with the power-supply voltage V_{DD};

a test section for producing at least two sets of (V_{DD}, t_{PD}) where the notation V_{DD} denotes a specific power-supply voltage V_{DD} peculiar to the first integrated circuit whereas the notation t_{PD} denotes a clock period t_{PD} which is the reciprocal of a maximum clock frequency giving a determination result indicating that the first integrated circuit is a good circuit at the specific power-supply voltage V_{DD}; and

a measurement section for producing at least two sets of (V_{DD}, t_{PD}) where the notation V_{DD} denotes a particular power-supply voltage V_{DD} peculiar to the second integrated circuit whereas the notation t_{PD} denotes a clock period t_{PD} obtained as a result of converting the operation speed obtained at the particular power-supply voltage V_{DD}.

The semiconductor evaluation method includes the steps of:

computing a clock period t_{PD} at any arbitrary power-supply voltage V_{DD} from first data (V_{DD1}, t_{PD1}) already produced by the test section or the measurement section, a threshold voltage V_{TH} and a coefficient α, which have already been produced by the test section or the measurement section as respectively the threshold voltage and coefficient of a given transistor, as well as a total wiring delay time t_{PWD} already produced by the test section or the measurement section;

providing best and worst cases of the first data (V_{DD1}, t_{PD1}), the threshold voltage V_{TH} and the coefficient α which have already been produced by the test section or the measurement section;

comparing a range having the minimum value of the computed clock periods t_{PD} as its lower limit and the maximum value of the computed clock periods t_{PD} as its upper limit with another measured measurement point (V_{DDi}, t_{PDi}); and

confirming the existence of a defect in the first integrated circuit if the other measured measurement point (V_{DDi}, t_{PDi}) is outside the range.

In accordance with a third embodiment of the present invention, there is provided a semiconductor evaluation program to be executed by a computer for carrying out semiconductor evaluation processing by making use of:

a first integrated circuit to be determined as a good or defective circuit in accordance with a combination of a power-supply voltage V_{DD} and a clock frequency;

a second integrated circuit serving as a source for providing information on an operation speed varying in accordance with the power-supply voltage V_{DD};

a test section for producing at least two sets of (V_{DD}, t_{PD}) where the notation V_{DD} denotes a specific power-supply voltage V_{DD} peculiar to the first integrated circuit whereas the notation t_{PD} denotes a clock period t_{PD} of a maximum clock frequency giving a determination result indicating that the first integrated circuit is a good circuit at the specific power-supply voltage V_{DD}; and

a measurement section for producing at least two sets of (V_{DD}, t_{PD}) where the notation V_{DD} denotes a particular power-supply voltage V_{DD} peculiar to the second integrated circuit whereas the notation t_{PD} denotes a clock period t_{PD} obtained as a result of converting the operation speed obtained at the particular power-supply voltage V_{DD}.

The semiconductor evaluation processing includes the steps of:

computing a clock period t_{PD} at any arbitrary power-supply voltage V_{DD} from first data (V_{DD1}, t_{PD1}) already produced by the test section or the measurement section, a threshold voltage V_{TH} and a coefficient α, which have already been produced by the test section or the measurement section as respectively the threshold voltage and coefficient of a given transistor, as well as a total wiring delay time t_{PWD} already produced by the test section or the measurement section;

providing best and worst cases of the first data (V_{DD1}, t_{PD1}), the threshold voltage V_{TH} and the coefficient α which have already been produced by the test section or the measurement section;

comparing a range having the minimum value of the computed clock periods t_{PD} as its lower limit and the maximum value of the computed clock periods t_{PD} as its upper limit with another measured measurement point (V_{DDi}, t_{PDi}); and

confirming the existence of a defect in the first integrated circuit if the other measured measurement point (V_{DDi}, t_{PDi}) is outside the range.

In accordance with the present invention:

the test section produces at least two sets of (V_{DD}, t_{PD}) where the notation V_{DD} denotes a specific power-supply voltage V_{DD} peculiar to the first integrated circuit whereas the notation t_{PD} denotes a clock period t_{PD} which is the reciprocal of a maximum clock frequency giving a determination result indicating that the first integrated circuit is a good circuit at the specific power-supply voltage V_{DD};

the measurement section produces at least two sets of (V_{DD}, t_{PD}) where the notation V_{DD} denotes a particular power-supply voltage V_{DD} peculiar to the second integrated circuit whereas the notation t_{PD} denotes a clock period t_{PD} obtained as a result of converting the operation speed obtained at the particular power-supply voltage V_{DD}; and

the computation section computes a clock period t_{PD} at any arbitrary power-supply voltage V_{DD} from first data (V_{DD}1, t_{PD}1) already produced by the test section or the measurement section, a threshold voltage V_{TH} and a coefficient α, which have already been produced by the test section or the measurement section as respectively the threshold voltage and coefficient of a given transistor, as well as a total wiring delay time t_{PWD} already produced by the test section or the measurement section.

By virtue of the present invention, it is possible to acquire information on an internal delay inside an LSI, carry out process monitoring, carry out a defect analysis and determine whether the LSI is good or defective without making use of any special circuit employed by the LSI.

### BRIEF DESCRIPTION OF THE DRAWINGS

FIG. 1 is a block diagram showing a typical configuration of a semiconductor evaluation apparatus according to an embodiment of the present invention;

FIG. 2 is an explanatory diagram referred to in description of a typical result produced by adoption of the Shmoo technique;

FIG. 3 is a diagram showing three plotted Shmoo lower limit lines obtained as a result of adoption of test methods carried out on LSIs of three different types respectively;

FIG. 4 is a diagram showing three estimated V_{DD}-t_{CLK} characteristic curves obtained as a result of estimating the parameters of a function F for the three Shmoo lower limit lines shown in the diagram of FIG. 3;

FIG. 5 is a diagram showing a plotted curve representing the estimated characteristic and measured value by measuring a relation between the read time of an SPAM evaluation circuit and a power-supply voltage V_{DD} at seven points;

FIG. 6 is a diagram showing four curves FN, FP, SN and SP representing data actually measured by making use of 142 evaluation circuits as curves each representing a repetition frequency distribution of the threshold voltages V_{TH} of transistors and a curve Est representing a repetition frequency distribution of estimated threshold voltages V_{TH};

FIG. 7 is a diagram showing differences between the distribution Est and the repetition-frequency distribution SP which are shown in FIG. 6:

FIG. 8 is a diagram showing V_{DD}-t_{CLK} characteristics measured at temperatures of 25 degrees C. and −25 degrees C. for samples A and B as well as four estimated curves for the measured characteristics;

FIG. 9 is a diagram showing characteristic points computed in the prediction of a normal range and two curves representing the power-supply voltage V_{DD}-t_{CLK} characteristics found for threshold voltages V_{TH} of 0.2 V and 0.8 V respectively;

FIG. 10A is a diagram showing the threshold voltage V_{TH} having an estimated value in the range 0.55 V to 0.625 V in 99% of certain wafers;

FIG. 10B is a diagram showing the threshold voltage V_{TH} having an estimated value in the range 0.55 V to 0.8 V in most of other wafers; and

FIG. 11 is a diagram showing flows of concrete processing carried out by the semiconductor evaluation apparatus according to the embodiment.

### DETAILED DESCRIPTION OF THE PREFERRED EMBODIMENTS

A preferred embodiment of the present invention is explained by referring to diagrams as follows.

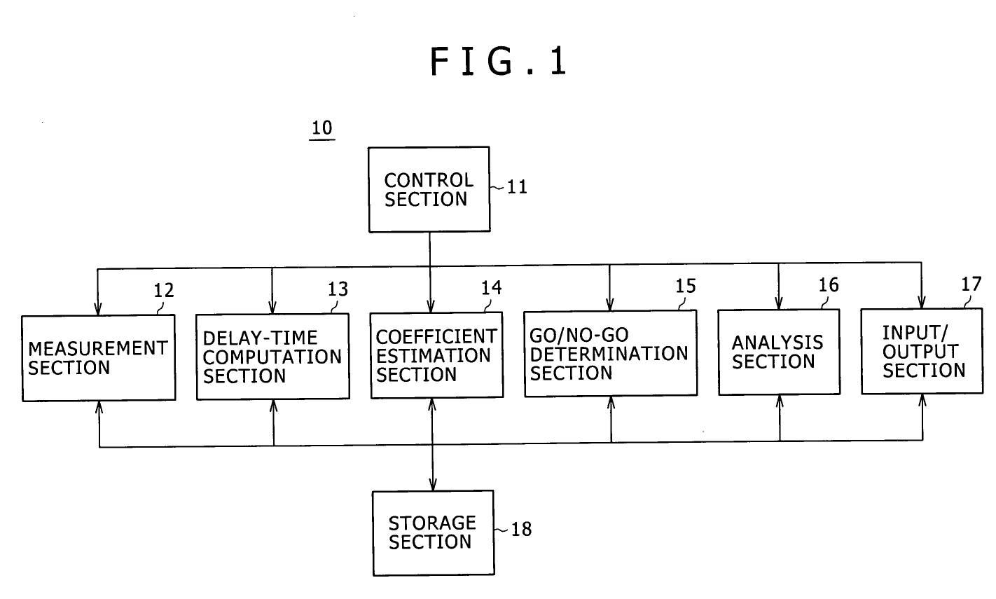

FIG. 1 is a block diagram showing a typical configuration of a semiconductor evaluation apparatus 10 according to an embodiment of the present invention.

As shown in FIG. 1, the semiconductor evaluation apparatus 10 employs a control section 11, a measurement section 12, a delay-time computation section 13, a coefficient estimation section 14, a go/no-go determination section 15, an analysis section 16, an input/output section 17 and a storage section 18.

The control section 11 controls the functional sections 12 to 18 in order to put them in a state of operating in a harmonious way.

The measurement section 12 applies a necessary signal to a measured LSI (or a measured integrated circuit), obtains a signal from the LSI and stores the signal obtained from the LSI in the storage section 18.

The delay-time computation section 13 computes a delay time from specified information stored in the storage section 18 and stores the delay time obtained as a result of the computation in the storage section 18.

The coefficient estimation section 14 estimates coefficients from a measurement result and specified information, which have been stored in the storage section 18, and storing the coefficient obtained as a result of the estimation in the storage section 18.

The go/no-go determination section 15 produces a result of determination as to whether an LSI is good or defective from an estimation result and a computed delay time, which have been stored in the storage section 18, and stores the result of the determination in the storage section 18.

The analysis section 16 carries out processing including a statistical process on the computed delay time and/or an estimated coefficient, which have been stored in the storage section 18 for each of a plurality of samples, and stores the result of the processing in the storage section 18.

The input/output section 17 transfers some or all of the results of computation based on measurement data, delay times, estimated coefficients, results of determination as to whether LSIs are good or defective and analysis results from the storage section 18 to an external recipient, acquires data of the same type as that stored in the storage section 18 from an external source and stores the acquired data in the storage section 18.

The typical configuration shown in FIG. 1 is the basic configuration of the semiconductor evaluation apparatus 10 and a more concrete configuration is explained as follows.

As a prerequisite for evaluation of a semiconductor, the semiconductor evaluation apparatus includes:

a first LSI serving as a first element to be determined as a good or defective circuit in accordance with a combination of a power-supply voltage V_{DD} and a clock frequency;

a second LSI serving as a second element serving as a source for providing information on an operation speed varying in accordance with the power-supply voltage V_{DD};

an LSI test section serving as a third element for producing at least two sets of (V_{DD}, t_{PD}) where the notation V_{DD} denotes a specific power-supply voltage V_{DD} peculiar to the first LSI whereas the notation t_{PD} denotes a clock period t_{PD} which is the reciprocal of a maximum clock frequency giving a determination result indicating that the first LSI is a good circuit at the specific power-supply voltage V_{DD}; and

an LSI measurement section serving as a fourth element for producing at least two sets of (V_{DD}, t_{PD}) where the notation V_{DD} denotes a particular power-supply voltage V_{DD} peculiar to the second LSI whereas the notation t_{PD} denotes a clock period t_{PD} obtained as a result of converting the operation speed obtained at the particular power-supply voltage V_{DD}.

According to this embodiment, the measurement section 12 functions as the LSI test section and the LSI measurement section.

In the semiconductor evaluation apparatus 10 according to the embodiment, the delay-time computation section 13 functions as a computation section for computing a clock period t_{PD} at any arbitrary power-supply voltage V_{DD} from first data (V_{DD1}, t_{PD1}) already produced by the LSI test section or the LSI measurement section, a threshold voltage V_{TH} and a coefficient α, which have already been produced by the LSI test section or the LSI measurement section as respectively the threshold voltage and coefficient of a given transistor, as well as a total wiring delay time t_{PWD} already produced by the LSI test section or the LSI measurement section.

In the semiconductor evaluation apparatus 10 according to this embodiment, the go/no-go determination section 15 executes the steps of:

providing best and worst cases of the first data (V_{DD1}, t_{PD1}), the threshold voltage V_{TH} and the coefficient α which have already been produced by the LSI test section or the LSI measurement section;

comparing a range having the minimum value of clock periods t_{PD} computed by the delay-time computation section 13 as its lower limit and the maximum value of clock periods t_{PD} computed by the delay-time computation section 13 as its upper limit with another measurement point (V_{DDi}, t_{PDi}) measured by the measurement section 12; and

confirming the existence of a defect in the first LSI if the other measured measurement point (V_{DDi}, t_{PDi}) is outside the range.

In the semiconductor evaluation apparatus 10 according to this embodiment, if the second and subsequent pieces of measured data (V_{DD}, t_{PD}) produced by the measurement section 12 functioning as the LSI test section or the LSI measurement section are all in the range between the minimum value and the maximum value, the coefficient estimation section 14 estimates a total wiring delay time t_{PWD} already measured by the measurement section 12 as the total wiring delay time of a longest signal delay path, a gate delay time t_{PGD} already measured by the measurement section 12 as the gate delay time of a gate as well as a threshold voltage V_{TH} and a coefficient α which have already been measured by the measurement section 12 as respectively the threshold voltage and coefficient of a transistor serving as the gate from the measured data (V_{DD}, t_{PD}).

In addition, in the semiconductor evaluation apparatus 10 according to this embodiment, the go/no-go determination section 15 also produces a result of determination as to whether the first or second LSI is a good or defective circuit on the basis of coefficients estimated by the coefficient estimation section 14.

In the semiconductor evaluation apparatus 10 according to this embodiment, coefficients estimated by the coefficient estimation section 14 are stored along with information on the first or second LSI associated with the coefficients in the storage section 18 which is provided as an internal or external storage section.

In addition, in the semiconductor evaluation apparatus 10 according to this embodiment, the analysis section 16 carries out an analysis by making use of information stored in the storage section 18.

In the semiconductor evaluation apparatus 10 according to this embodiment, the input/output section 17 is configured to function as an input unit for acquiring a separately obtained set (V_{DD}, t_{PD}) from an external source in order to carry out some or all of the computation processing of the delay-time computation section 13, the go/no-go determination processing of the go/no-go determination section 15, the estimation processing of the coefficient estimation section 14, the processing to store information in the storage section 18 and the analysis processing of the analysis section 16.

The semiconductor evaluation apparatus 10 having the configuration described above can acquire information on an internal delay of an LSI, carries out process monitoring, conducting an analysis of whether an LSI is a good or defective product and performs processing to determine whether an LSI is a good or defective product without making use of any special circuit.

A processing principle and matters related to the principle are explained as follows.

### <Processing Principle>

In general, the delay time t_{PD} of a signal propagation path having wires and gates as its elements is a sum (t_{PWD}+t_{PGD}) where the notation t_{PWD} denotes delay times caused by the wires whereas the notation t_{PGD} denotes delay times caused by the gates. Thus, the delay time t_{PD} is expressed by the following equation:

$$\begin{matrix}[ Formulas 1 ] & \\ {t}_{PD} = {t}_{PDW} + {t}_{PGD} & ( 1 ) \\ {t}_{PWD} = {\sum }_{i = 1}^{n} {t}_{{WD}_{i}} & ( 2 ) \\ {t}_{PGD} = {\sum }_{i = 1}^{m} {t}_{{GD}_{i}} & ( 3 )\end{matrix}$$

Notations t_{WDi} and n used in Eq. (2) denote the time delay caused by one wire and the number of wires respectively. On the other hand, the notations t_{GDi} and m used in Eq. (3) denote the time delay caused by one gate and the number of gates respectively.

The time delay t_{GD} of a MOSFET gate can be found from a load capacitance CL and a drain saturation current I_{Dsat} in accordance with the following equation:

$$\begin{matrix}[ Formula 2 ] & \\ {t}_{GD} = \frac{{C}_{L} {V}_{DD}}{{I}_{Dsat}} & ( 4 )\end{matrix}$$

The drain saturation current I_{Dsat} is expressed as follows:

### [Formula 3]

I_{Dsat}=0.5K_{D}(V_{DD}−V_{TH})^{α} (5)

In the above equation, the notation K_{D} denotes the driving power of the gate, notation V_{TH} denotes the threshold voltage of the transistor serving as the gate and notation α denotes a constant coefficient determined by the structure of the transistor. Typically, the constant coefficient α has a value in the range 1 to 2. Inserting the expression on the right-hand side of Eq. (5) into Eq. (4) as a substitute for I_{Dsat} yields Eq. (6) given as follows:

$$\begin{matrix}[ Formula 4 ] & \\ {t}_{GD} = \frac{2 {C}_{L} {V}_{DD}}{{{K}_{D} ( {V}_{DD} - {V}_{TH} )}^{α}} & ( 6 )\end{matrix}$$

It is to be assumed that the load capacitance C_{L}, the driving power K_{D} of the gate as well as the threshold voltage V_{TH} and constant (or coefficient) α are independent of the power-supply voltage V_{DD}. In this case, a gate time delay ratio R_{D} representing the ratio of a gate delay time t_{GD} at any specific power-supply voltage V_{DD} to a gate delay time t_{GDR} at a reference power-supply voltage V_{DDR} is given as follows:

$$\begin{matrix}[ Formula 5 ] & \\ {R}_{D} = \frac{{t}_{GD}}{{t}_{GDR}} = \frac{{{V}_{DD} ( {V}_{DDR} - {V}_{TH} )}^{α}}{{{V}_{DDR} ( {V}_{DD} - {V}_{TH} )}^{α}} & ( 7 )\end{matrix}$$

Thus, the delay time t_{GD} of the gate is expressed as follows:

### [Formula 6]

t_{GD}=t_{GDR}R_{D} (8)

Inserting the expression on the right-hand side of Eq. (8) into Eq. (3) as a substitute for t_{GD} yields the following equation:

$$\begin{matrix}[ Formula 7 ] & \\ {t}_{PGD} = {\sum }_{i = 1}^{m} {t}_{{GDR}_{i}} {R}_{{D}_{i}} & ( 9 )\end{matrix}$$

In the above equation, notation t_{GDRi} denotes the gate delay time t_{GDR} of any particular gate at the reference power-supply voltage V_{DDR} whereas notation R_{Di} denotes the delay ratio R_{D} of the particular gate.

If the gates each have the same threshold voltage V_{TH} and the same coefficient α, the gates each have the same delay ratio Rd. In this case, Eq. (9) is converted into the following equation:

### [Formula 8]

t_{PGD}=t_{PGDR}R_{D} (10)

In the above equation, notation t_{PGDR} denotes a sum expressed as follows:

$$\begin{matrix}[ Formula 9 ] & \\ {t}_{PGDR} = {\sum }_{i = 1}^{m} {t}_{{GDR}_{i}} & ( 11 )\end{matrix}$$

Inserting the expression on the right-hand side of Eq. (10) into Eq. (1) as a substitute for t_{PGD} yields the following equation:

### [Formula 10]

t_{PD}=t_{PWD}+t_{PGDR}R_{D} (12)

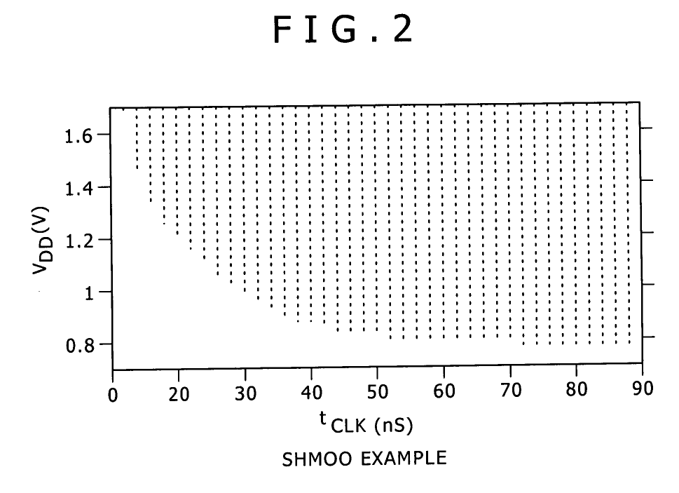

FIG. 2 is an explanatory diagram referred to in description of a typical result produced by adoption of the Shmoo technique. The figure shows plotted levels of the power-supply voltage V_{DD} in a dark area as levels each giving a determination result indicating that the LSI is a good LSI at a value of the clock period t_{CLK}. This relation between the power-supply voltage V_{DD} and the clock period t_{CLK} is obtained in a scan test carried out on products of type A.

The relation shown in FIG. 2 indicates that, at a fixed power-supply voltage V_{DD}, an increased clock frequency reduces the clock period t_{CLK} to a value shorter than a delay time in the LSI, conceivably giving a determination result indicating a defective LSI.

A dark upper/right portion of the figure is an area representing determination results each indicating that the LSI is a good LSI whereas a white lower/left portion of the figure is an area representing determination results each indicating that the LSI is a defective LSI. That is to say, the longer the clock period t_{CLK} or the lower the clock frequency and the higher the power-supply voltage V_{DD}, the higher the probability that the result of determination indicates that the LSI is a good LSI. At any point on the boundary between the dark upper/right and white lower/left portions of the Shmoo technique, if the decrementing step of the clock period t_{CLK} is small enough for a given incrementing step of the power-supply voltage V_{DD}, the clock period t_{CLK} is not reduced to a value shorter than the delay time of a signal propagating in the LSI, but reduced to a value equal to the delay time at the worst. In the following description, the boundary between the dark upper/right and white lower/left portions of the Shmoo technique is referred to as a Shmoo lower limit line. If the power-supply voltage V_{DD} is decreased along the Shmoo lower limit line, the gate delay time increases, reducing the maximum clock frequency F_{Max}. If the power-supply voltage V_{DD} is decreased to a gate-operatable voltage, the gate enters a saturated state. Thus, the Shmoo lower limit line is a V_{DD}-F_{Max} characteristic representing a relation between the power-supply voltage V_{DD} and the maximum clock frequency F_{Max}, at a clock frequency above which the result of the determination will indicate that the LSI is a defective LSI. In addition, at any given clock frequency corresponding to any point on the Shmoo lower limit line, the power-supply voltage V_{DD} corresponding to the point is the gate-operatable voltage. At this point, the clock period t_{CLK} coincides with the longest delay time t_{PD} among those of signal propagation paths detected in the test.

If the signal propagation path having the longest delay time t_{PD} is not dependent on the power-supply voltage V_{DD}, the power-supply voltage V_{DD}-F_{Max} characteristic can be expressed as follows:

### [Formula 11]

t_{CLK}=t_{PWD}+t_{PGDR}R_{D} (13)

As is obvious from Eqs. (7) and (12), the delay time t_{PD} is a function of V_{DD}, V_{DDR}, V_{TH}, α, t_{PWD} and t_{PGDR}. Thus, Eq. (12) can be rewritten into an equation representing the delay time t_{PD} as the value of a function F as follows.

### [Formula 12]

t_{PD}=F(V_{DD},V_{DDR},Vₜₕ,α,t_{PED},t_{PGDR}) (14)

By adoption of some methods, the parameters other than the power-supply voltage V_{DD} can be estimated. Then, the values of the other parameters as well as the power-supply voltage V_{DD} are substituted into Eq. (14) in order to find the delay time t_{PD}.

Where each of points i.e., a point P₁ (t_{PD1}, V_{DD1}) and a point P₂ (t_{PD2}, V_{DD2}) is inserted into Eq. (12) as a substitute for the delay time t_{PD}, following equations can be given:

### [Formula 13]

t_{PD1}=t_{PWD}+t_{PGDR}R_{D1} (15)

t_{PD2}=t_{PWD}+t_{PGDR}R_{D2} (16)

If the other power-supply voltage V_{DD1} is used as the reference power-supply voltage V_{DDR}, the gate time delay ratio R_{D1} has a value of 1.

With the gate time delay ratio R_{R1} having a value of 1, subtraction of Eq. (16) from Eq. (15) yields the following equation:

$$\begin{matrix}[ Formula 14 ] & \\ {t}_{PGDR} = \frac{{t}_{PD 1} - {t}_{PD 2}}{1 - {R}_{D 2}} & ( 17 )\end{matrix}$$

Eq. (15) can be rewritten into an equation for expressing the wire time delay t_{PWD} as follows:

### [Formula 15]

t_{PWD}=t_{PD1}−t_{PGDR} (18)

Since the power-supply voltage V_{DD1} is used as the reference power-supply voltage V_{DDR} as described above, the gate time delay ratio Rd2 can be found in accordance with Eq. (7) as follows:

$$\begin{matrix}[ Formula 16 ] & \\ {R}_{D 2} = \frac{{{V}_{DD 2} ( {V}_{DD 1} - {V}_{TH} )}^{α}}{{{V}_{DD 1} ( {V}_{DD 2} - {V}_{TH} )}^{α}} & ( 19 )\end{matrix}$$

From the above equations, the parameters of the function F on the right-hand side of Eq. (14) can be found in accordance with the following procedure.

1): Assume any arbitrary values ̂V_{TH} and ̂α of the threshold voltage V_{TH} and the coefficient α respectively.
2): Insert the values ̂V_{TH} and ̂α of the threshold voltage V_{TH} and the coefficient α respectively into Eq. (19) as substitutes for V_{TH} and α respectively in order to find an estimated value ̂R_{D2} of the gate time delay ratio R_{D2}.
3): Insert the estimated value ̂R_{D2} of the gate time delay ratio R_{D2} into Eq. (17) as a substitute for R_{D2} in order to find an estimated value ̂t_{PGDR} of the sum t_{PGDR} expressed by Eq. (11).
4): Insert the estimated value ̂t_{PGDR} of the sum t_{PGDR} into Eq. (18) as a substitute for t_{PGDR} in order to find an estimated value ̂_{PWD} of the wire time delay t_{PWD}.

Then, an estimated value t_{PDi} of the delay time t_{PDi} for a measurement point (t_{PD}, V_{DD}) can be found from the parameters estimated in accordance with the above procedure by making use of the function F as follows:

### [Formula 17]

\hat{t}_{PDi}=F(V_{DD1},\hat{V}_{TH},\hat{α},\hat{t}_{PWD},\hat{t}_{PGDR}) (20)

An estimation error for each measurement point can be found as follows:

### [Formula 18]

eᵢ=\hat{t}_{PDi}−t_{PDi} (21)

Then, proper values of the threshold voltage V_{TH} and the coefficient α are determined. The proper values of the threshold voltage V_{TH} and the coefficient α are values that minimize evaluation expressions. The evaluation expressions are typically expressions expressed in terms of the average value, variance and/or maximum deviation of the estimation errors. If the values of the threshold voltage V_{TH} and the coefficient α are determined, the power-supply voltage V_{DD}-t_{PD} characteristic can be estimated for each point other than the measurement points.

It is to be noted that the estimated V_{DD}-t_{PD} characteristic always matches the true characteristic at each of the measurement points P₁ and P₂. Thus, in order to find an optimum condition, measurements at three or more points are required. Of course, since Eq. (12) resembles Eq. (13), by replacing the delay time t_{PD} with the clock period t_{CLK}, a V_{DD}-t_{CLK} characteristic can also be estimated as well.

### <Verification>

From data of actual LSIs, the validity of the principle can be verified. Since the transistor coefficient α used as one of the parameters of the function F is determined by the structure of the transistor, the coefficient α of the transistor can be determined as a fixed value in advance prior to the estimation. For all transistors used in the embodiment, the coefficient α was fixed at 2.

As a method for minimizing the estimation errors, there was adopted the simplest technique for minimizing the average value E of the estimation errors. In accordance with this adopted method, the threshold voltage V_{TH} of the transistor was increased from 0.2 V to 1.5 V step by step with each step set at 0.001 V. A threshold voltage V_{TH} providing a minimum value of the average value E of the estimation errors was identified and used as another parameter of the function F. Then, the estimation processing was carried out by using the parameters obtained in this way.

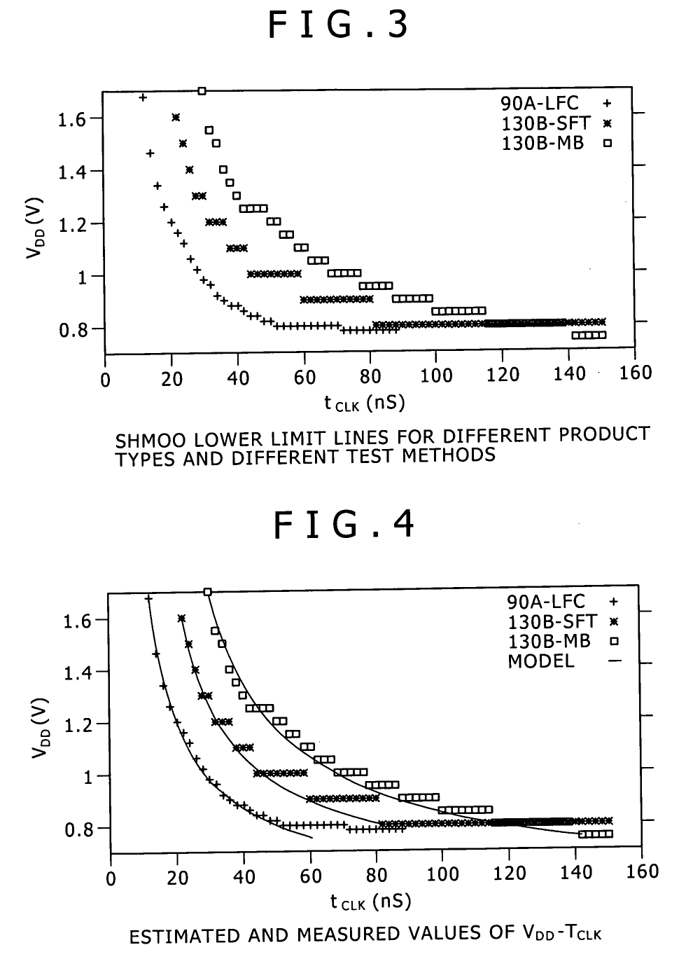

FIG. 3 is a diagram showing three plotted Shmoo lower limit lines obtained as a result of adoption of test methods carried out on LSIs of three different types respectively.

To be more specific, in the figure, notation 90A-LFC denotes a Shmoo lower limit for a high-speed scan test carried out on LSIs each fabricated by making use of a 90 nm CMOS process as an LSI of type A. Notation 130B-SFT denotes a Shmoo lower limit for a low-speed scan test carried out on LSIs each fabricated by making use of a 130 nm CMOS process as an LSI of type B. Notation 130B-MB denotes a Shmoo lower limit for a memory test carried out on LSIs each fabricated by making use of a 90 nm CMOS process as an LSI of type B.

FIG. 4 is a diagram showing three estimated V_{DD}-t_{CLK} characteristic curves obtained as a result of estimating the parameters for the three Shmoo lower limit lines shown in the diagram of FIG. 3. In the diagram of FIG. 4, the three estimated V_{DD}-t_{CLK} characteristic curves are compared with actually measured values representing respectively the three Shmoo lower limit lines shown in the diagram of FIG. 3.

As is obvious from the diagram of FIG. 4, the three curves well match the actually measured values.

For each of the 3 different Shmoo lower limit lines, Table 1 shows the parameters of the function F, the average value of estimation errors obtained as a result of the comparison and a measurement-point count n representing the number of measurement points used in the estimation of the parameters. As shown in the table, the average values are all within a range of ±0.01 ns.

TABLE 1
Parameters used in the estimation explained by
referring to FIG. 4.

| Shmoo | | Ē | V_{TH} | T_{PWD} | T_{PGDR} |
|---|---|---|---|---|---|
| name | n | (ns) | (ns) | (ns) | (ns) |
| 90A-LFC | 19 | 0.00750 | 0.58 | 7.5 | 4.5 |
| 130B-SFT | 9 | 0.00447 | 0.44 | 7.8 | 14.2 |
| 130B-MB | 18 | −0.00475 | 0.41 | 9.5 | 20.5 |

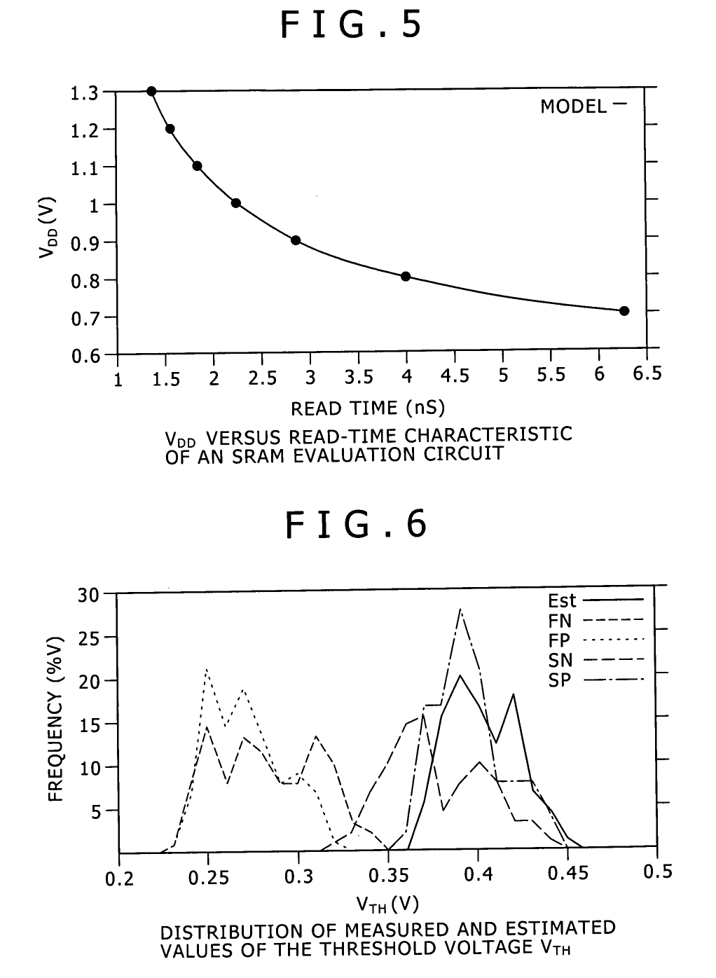

FIG. 5 is a diagram showing a plotted curve representing a relation between the read time of an SRAM evaluation circuit and the power-supply voltage V_{DD}. The curve was obtained by connecting seven measurement points at each of which the read time and the power-supply voltage V_{DD} were measured.

The average value of estimation errors and their standard deviation are respectively 0.00045 and 0.01021 which are extremely small values. The SRAM evaluation circuit is provided with monitor transistors for used transistors of four different types. The threshold voltage V_{TH} of each transistor can be measured directly.

FIG. 6 is a diagram showing four distributions FN, FP, SN and SP each representing the repetition-frequency distribution of the threshold voltages V_{TH} of transistors and a distribution Est representing estimated threshold voltages V_{TH}. The four distributions were obtained as a result of actual measurements carried out on 142 evaluation circuits.

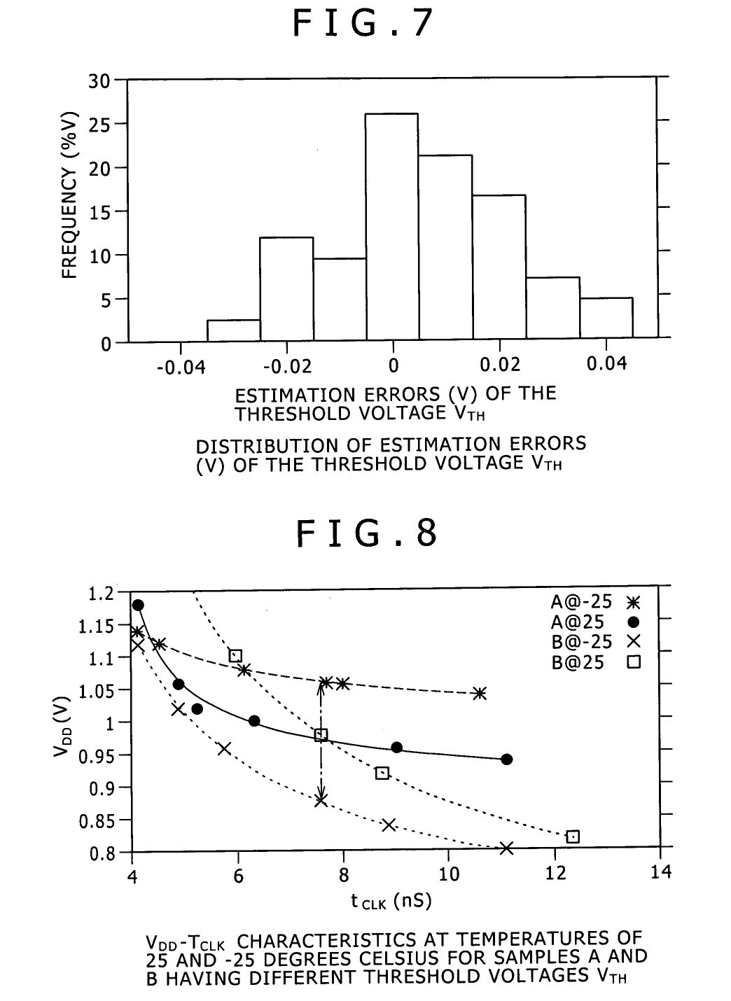

As shown in the figure, the distribution Est representing estimated threshold voltages _{VTH} is close to the repetition-frequency distribution SP. The differences between the distribution Est and the repetition-frequency distribution SP are shown in FIG. 7. That is to say, FIG. 7 is a diagram showing estimation errors between the distribution Est and the repetition-frequency distribution SP. As shown in the figure, the estimation errors are within a range of ±0.05 V.

### <Typical Application>

The following description explains a typical application from V_{DD}-t_{CLK} data at six points for tests carried out on SRAMs mass produced by making use of a 90 nm process as SRAMs of type C.

1: Discrimination of Products with Abnormal Characteristics

LSI products each having an abnormal characteristic caused by miniaturization are inadvertently created, raising a problem.

FIG. 8 is a diagram showing V_{DD}-t_{CLK} characteristics measured at temperatures of 25 degrees C. and −25 degrees C. for samples A and B as well as four estimated curves for the measured characteristics.

The performance of the LSI is assured if the LSI is operated at a power-supply voltage V_{DD} of 1.0 V and a frequency of 132 MHz. At the temperature of 25 degrees C., both the samples A and B of the LSI barely meet the demand for the assurance of the performance.

At the temperature of −25 degrees C., however, the samples A and B operate much differently from the operations at the temperature of 25 degrees C.

To be more specific, sample A operates only at power-supply voltages V_{DD} at least equal to 1.06 V. On the other hand, the sample B operates even at a power-supply voltage V_{DD} of 0.86 V provided that the clock frequency does not exceed 132 MHz. Since a test carried out at a low temperature is costly, there is raised a demand that an LSI product having an abnormal characteristic be discriminated at a room temperature. With only a result measured at one point, however, it is generally impossible to distinguish the samples A and B from each other.

Nevertheless, the estimated threshold voltage V_{TH} of the sample B is 0.86 V while the estimated threshold voltage _{VTH} of the sample A is 0.49 V. From the estimated threshold voltage V_{TH}, it is thus possible to distinguish the samples A and B from each other.

### 2: Normal Range Prediction

It is necessary to carry out the V_{TH}-t_{CLK} measurement a plurality of times by varying the power-supply voltage V_{DD} and the clock frequency t_{CLK} each time the measurement is performed. Thus, the measurement time is long.

In order to solve the problem of the long measurement time, upper and lower limit conditions are set from an initial measurement point and a normal range of other measured values is predicted in advance. Then, if a measured value is found outside the normal range, the measurement is terminated. In this way, the length of the measurement time can be reduced.

With assumed first values of V_{DD}=1 V, t_{CLK}=13.7 ns, α=2 and t_{PWD}=0, the power-supply voltage V_{DD}-t_{CLK} characteristics can be found for threshold voltages V_{TH} of 0.2 V and 0.8 V in accordance with Eq. (14).

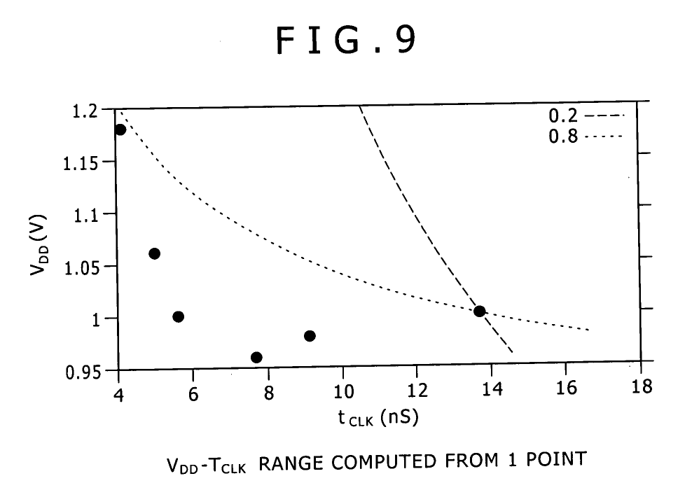

FIG. 9 is a diagram showing characteristic points computed in the prediction of a normal range and two curves representing the power-supply voltage V_{DD}-t_{CLK} characteristics found for threshold voltages _{VTH} of 0.2 V and 0.8 V respectively in accordance with Eq. (14).

Since the second 0.98V-9 ns characteristic point from the right side is located at a position beneath the lower-limit line, being separated far away from the lower-limit line, an LSI product displaying this second 0.98V-9 ns characteristic point can be determined to be a defective product. Of course, the precision of an error prediction range can be improved by making use of two points.

### 3: Acquisition of Process Variations

Estimated values of t_{PWD}, t_{PGDR}, V_{TH} and α, which are obtained from each LSI, are saved and gathered for every wafer and every lot to be used as process control indicators.

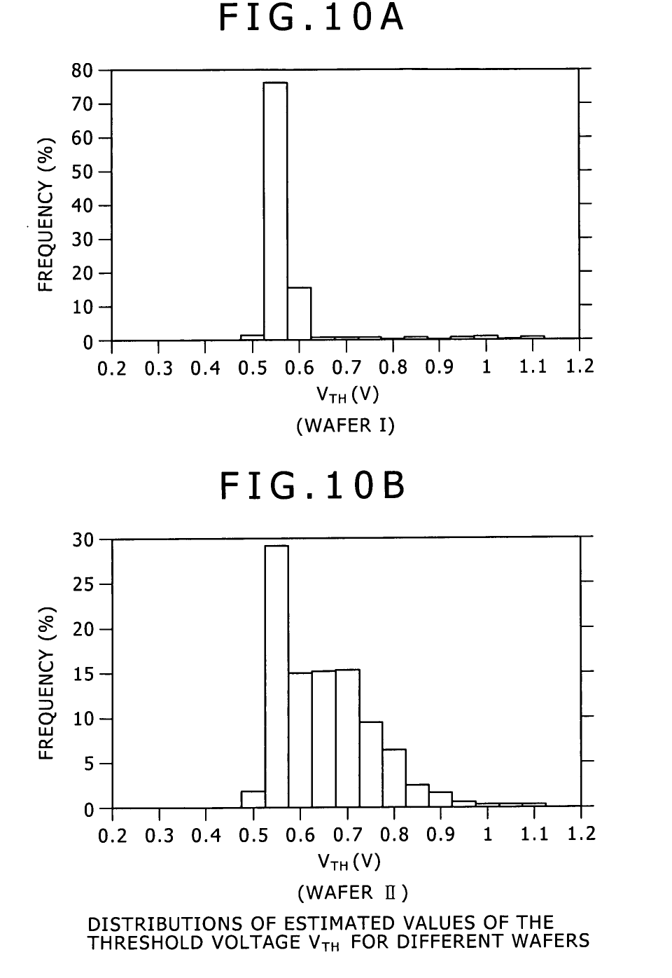

FIGS. 10A and 10B are each a diagram showing an estimated-V_{TH} repetition frequency distribution for a wafer. As shown in FIG. 10A, the threshold voltage V_{TH} has an estimated value in the range 0.55 V to 0.625 V in 99% of wafers I. As shown in FIG. 10B, on the other hand, the threshold voltage _{VTH} has an estimated value in the range 0.55 V to 0.8 V in most of wafers II. The range 0.55 V to 0.8 V reveals widely spread process variations.

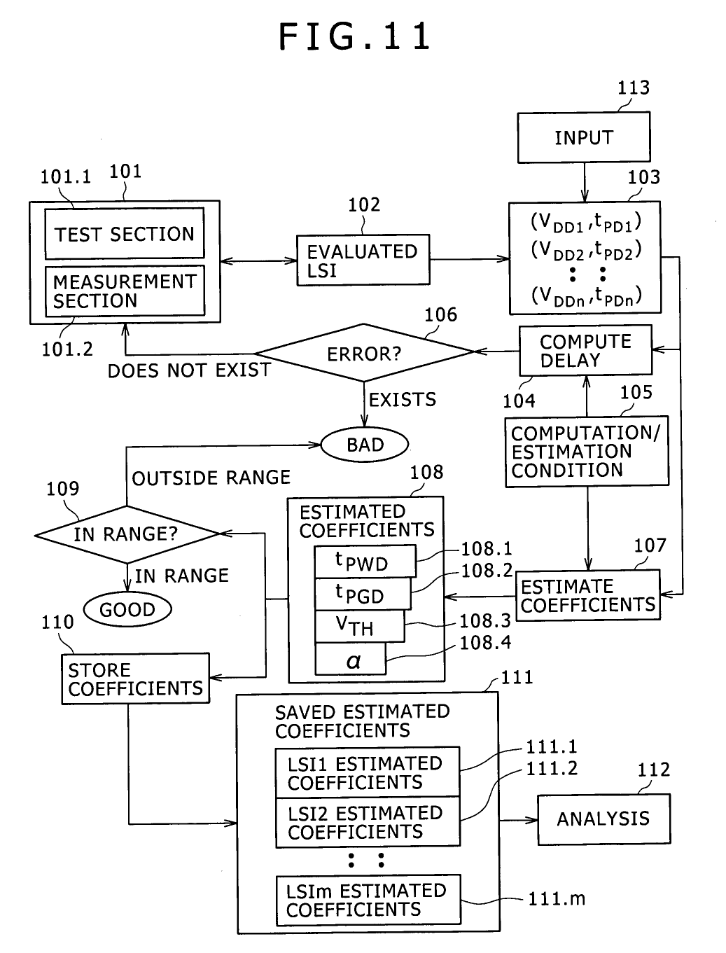

By referring to FIG. 11, the following description explains processing carried out by the semiconductor evaluation apparatus 10, which has the functional configuration shown in FIG. 1, on the basis of the principle described above.

It is to be noted that FIG. 11 is a diagram showing flows of concrete processing carried out by the semiconductor evaluation apparatus 10 according to the embodiment. In the diagram of FIG. 11, reference numeral 101.1 denotes a test section, reference numeral 101.2 denotes a measurement section and reference numeral 102 denotes an LSI serving as an object of evaluation.

The test section 101.1 is a unit for determining whether the evaluated LSI 102 is a good or defective product by changing the power-supply voltage V_{DD} applied to the evaluated LSI 102 and changing the frequency of a clock signal supplied to the evaluated LSI 102. In the following description, the frequency of a clock signal supplied to the evaluated LSI 102 is referred to as a clock frequency. The measurement section 101.2 is a unit for establishing a relation between the operation speed of the evaluated LSI 102 and the power-supply voltage V_{DD} applied to the evaluated LSI 102. The semiconductor evaluation apparatus 10 determines a period t_{PD} which is the reciprocal of a maximum clock frequency detected by the test section 101.1. In order for an evaluated LSI 102 to be determined as a good product, the evaluated LSI 102 must function normally at clock frequencies in a range limited on the upper side by the maximum clock frequency at 2 or more different power-supply voltages V_{DD}. The period t_{PD} is also the reciprocal of an operation frequency measured by the measurement section 101.2 as the operation speed of the evaluated LSI 102.

In delay computation processing 104, a period t_{PD} is computed for each other measurement point from first values (V_{DD1}, t_{PD1}) and a computation condition 105 to result in a set (V_{DD}, t_{PD}) for every measurement point. The computed sets of (V_{DD}, t_{PD}) are saved in a memory as stored sets (V_{DD}, t_{PD}) 103. In addition, upper and lower limits of a range for the computed periods t_{PD} are set. In error determination processing 106, the semiconductor evaluation apparatus 10 compares a set of (V_{DD}, t_{PD}) computed for a measurement point with the range. If the result of the comparison indicates that the computed set of (V_{DD}, t_{PD}) is outside the range, the evaluated LSI 102 is determined to be a defective product.

If the sets of (V_{DD}, t_{PD}) computed for all measurement points are within the range, on the other hand, coefficient estimation processing 107 is carried out in order to estimate coefficients 108 from the stored sets (V_{DD}, t_{PD}) 103 and an estimation condition 105. The estimated coefficients 108 are the wire delay time t_{PWD} of the longest delay path, the gate delay time t_{PGD} of a gate as well as the threshold voltage V_{TH} and coefficient α of a transistor functioning as the gate.

In range comparison processing 109, the estimated coefficients 108 are compared with a range specified in advance. If the result of the comparison indicates that the estimated coefficients 108 are outside the range, the evaluated LSI 102 is determined to be a defective product. If the result of the comparison indicates that the estimated coefficients 108 are within the range, on the other hand, the evaluated LSI 102 is determined to be a good product.

In coefficient storing processing 110, the estimated coefficients 108 are stored in an external memory along with information used for identifying the evaluated LSI 102 associated with the estimated coefficients 108 as coefficients included in a saved estimated coefficient group 111 without regard to whether the evaluated LSI 102 is determined to be a good product or a defective product.

Then, an analysis 112 is carried out by making use of the saved estimated coefficient group 111.

In the mean time, an external set (V_{DD}, t_{PD}) 113 obtained separately is received from an external source and converted into the same format as the internal format of the stored sets (V_{DD}, t_{PD}) 103. Then, the external set (V_{DD}, t_{PD}) 113 is subjected to the delay computation processing 104, the error determination processing 106, the coefficient estimation processing 107, the range comparison processing 109, the coefficient storing processing 110 and the analysis 112.

As explained above, in accordance with the embodiment, the delay-time computation section 13 computes a clock period t_{PD} at any arbitrary power-supply voltage V_{DD} from first data (V_{DD1}, t_{PD1}) already produced by the LSI test section or the LSI measurement section, a threshold voltage V_{TH} and a coefficient α which have already been produced by the LSI test section or the LSI measurement section as the threshold voltage as coefficient of a given transistor as well as a total wiring delay time t_{PWD} already produced by the LSI test section or the LSI measurement section.

The go/no-go determination section 15 executes the steps of:

providing best and worst cases of the first data (V_{DD1}, t_{PD1}), the threshold voltage V_{TH} and the coefficient α which have already been produced by the measurement section 12 functioning as the LSI test section or the LSI measurement section;

comparing a range having the minimum value of clock periods t_{PD} computed by the delay-time computation section 13 as its lower limit and the maximum value of clock periods t_{PD} computed by the delay-time computation section 13 as its upper limit with another measurement point (V_{DDi}, t_{PDi}) measured by the measurement section 12; and

confirming the existence of a defect in the first integrated circuit if the other measured measurement point (V_{DDi}, t_{PDi}) is outside the range.

If the second and subsequent pieces of measured data (V_{DD}, t_{PD}) produced by the measurement section 12 functioning as the LSI test section or the LSI measurement section are all in the range having the minimum value of clock periods t_{PD} computed by the delay-time computation section 13 as its lower limit and the maximum value of clock periods t_{PD} computed by the delay-time computation section 13 as its upper limit, the coefficient estimation section 14 estimates a total wiring delay time t_{PWD} already measured by the measurement section 12 as the total wiring delay time of a longest signal delay path, a gate delay time t_{PGD} already measured by the measurement section 12 as the gate delay time of a gate as well as a threshold voltage V_{TH} and a coefficient α which have already been measured by the measurement section 12 as respectively the threshold voltage and coefficient of a transistor serving as the gate from the measured data (V_{DD}, t_{PD}).

The go/no-go determination section 15 also produces a result of determination as to whether the first or second LSI is a good or defective circuit on the basis of coefficients estimated by the coefficient estimation section 14. The coefficients estimated by the coefficient estimation section 14 are stored along with information on the first or second LSI associated with the coefficients in the storage section 18 which is provided as an internal or external storage section.

The analysis section 16 carries out an analysis by making use of information stored in the storage section 18. Thus, the semiconductor evaluation apparatus 10 having the configuration described above is capable of acquiring information on an internal delay of an LSI, carrying out process monitoring, conducting an analysis of whether an LSI is a good or defective product and performing processing to determine whether an LSI is a good or defective product without making use of any special circuit.

It is to be noted that the semiconductor evaluation method explained before in detail can be implemented by a program to be executed by the CPU of a computer or the like in accordance with the procedure also described earlier. The program is typically recorded in advance in a recording medium. The program is then installed into a storage section employed in the computer when the recording medium is mounted on the computer. Finally, the program is loaded into a memory such as a RAM to be executed by the CPU. Examples of the recording medium are a semiconductor memory, a magnetic disk, an optical disk and a floppy (registered trademark) disk.

In addition, it should be understood by those skilled in the art that a variety of modifications, combinations, sub-combinations and alterations may occur, depending on design requirements and other factors insofar as they are within the scope of the appended claims or the equivalents thereof.

What is claimed is:

1. A semiconductor evaluation apparatus comprising:
a first integrated circuit to be determined as a good or defective circuit in accordance with a combination of a power-supply voltage V_{DD} and a clock frequency;
a second integrated circuit serving as a source for providing information on an operation speed varying in accordance with said power-supply voltage V_{DD};
a test section for producing at least two sets of (V_{DD}, t_{PD}) where notation V_{DD} denotes a specific power-supply voltage V_{DD} peculiar to said first integrated circuit whereas notation t_{PD} denotes a clock period t_{PD} which is the reciprocal of a maximum clock frequency giving a determination result indicating that said first integrated circuit is a good circuit at said specific power-supply voltage V_{DD};
a measurement section for producing at least two sets of (V_{DD}, t_{PD}) where notation V_{DD} denotes a particular power-supply voltage V_{DD} peculiar to said second integrated circuit whereas notation t_{PD} denotes a clock period t_{PD} obtained as a result of converting said operation speed obtained at said particular power-supply voltage V_{DD}; and
a computation section for computing a clock period t_{PD} at any arbitrary power-supply voltage V_{DD} from first data (V_{DD1}, t_{PD1}) already produced by said test section or said measurement section, a threshold voltage _{VTH} and a coefficient α, which have already been produced by said test section or said measurement section as respectively the threshold voltage and coefficient of a given transistor, as well as a total wiring delay time t_{PWD} already produced by said test section or said measurement section.

2. The semiconductor evaluation apparatus according to claim 1, further comprising
a go/no-go determination section for producing a result of determination as to whether said first integration circuit is good or defective by execution of the steps of:
providing best and worst cases of said first data (V_{DD1}, t_{PD1}), said threshold voltage V_{TH} and said coefficient α which have already been produced by said test section or said measurement section;
comparing a range having the minimum value of clock periods t_{PD} computed by said computation section as its lower limit and the maximum value of clock periods t_{PD} computed by said computation section as its upper limit with another measured measurement point (V_{DDi}, t_{PDi}); and
confirming the existence of a defect in said first integrated circuit if said other measured measurement point (V_{DDi}, t_{PDi}) is outside said range.

3. The semiconductor evaluation apparatus according to claim 2, further comprising
a coefficient estimation section for estimating values of said total wiring delay time t_{PWD} already measured by said test section or said measurement section as the total wiring delay time of a longest signal delay path, a gate delay time t_{PGD} already measured by said test section or said measurement section as the gate delay time of a gate as well as said threshold voltage V_{TH} and said coefficient α which have already been measured by said test section or said measurement section as respectively the threshold voltage and coefficient of a transistor serving as said gate from all data (V_{DD}, t_{PD}) measured by said the test section or said measurement section if second and subsequent pieces of said measured data (V_{DD}, t_{PD}) are all in said range.

4. The semiconductor evaluation apparatus according to claim 3 wherein, on the basis of coefficients estimated by said coefficient estimation section, said go/no-go determination section produces a result of determination as to whether said first integrated circuit is good or defective or whether said second integrated circuit is good or defective.

5. The semiconductor evaluation apparatus according to claim 3 wherein coefficient estimated by said coefficient estimation section is stored in an internal or external storage section along with information on said first or second integrated circuit.

6. The semiconductor evaluation apparatus according to claim 5, further comprising
an analysis section for carrying out an analysis by making use of said estimated coefficients and said integrated-circuit information, which have been stored in said storage section.

7. The semiconductor evaluation apparatus according to any one of claims 1 to 6, further comprising
an input section for acquiring a separately obtained set of (V_{DD}, t_{PD}) from an external source.

8. A semiconductor evaluation method making use of
a first integrated circuit to be determined as a good or defective circuit in accordance with a combination of a power-supply voltage V_{DD} and a clock frequency,
a second integrated circuit serving as a source for providing information on an operation speed varying in accordance with said power-supply voltage V_{DD},
a test section for producing at least two sets of (V_{DD}, t_{PD}) where notation V_{DD} denotes a specific power-supply voltage V_{DD} peculiar to said first integrated circuit whereas notation t_{PD} denotes a clock period t_{PD} which is the reciprocal of a maximum clock frequency giving a determination result indicating that said first integrated circuit is a good circuit at said specific power-supply voltage V_{DD}, and
a measurement section for producing at least two sets of (V_{DD}, t_{PD}) where notation V_{DD} denotes a particular power-supply voltage V_{DD} peculiar to said second integrated circuit whereas notation t_{PD} denotes a clock period t_{PD} obtained as a result of converting said operation speed obtained at said particular power-supply voltage V_{DD},
said semiconductor evaluation method comprising the steps of:
computing a clock period t_{PD} at any arbitrary power-supply voltage V_{DD} from first data (V_{DD1}, t_{PD1}) already produced by said test section or said measurement section, a threshold voltage V_{TH} and a coefficient α, which have already been produced by said test section or said measurement section as respectively the threshold voltage and coefficient of a given transistor, as well as a total wiring delay time t_{PWD} already produced by said test section or said measurement section;
providing best and worst cases of said first data (V_{DD1}, t_{PD1}), said threshold voltage V_{TH} and said coefficient α, which have already been produced by said test section or said measurement section;
comparing a range having the minimum value of said computed clock periods t_{PD} as its lower limit and the maximum value of said computed clock periods t_{PD} as its upper limit with another measured measurement point (V_{DDi}, t_{PDi}); and
confirming the existence of a defect in said first integrated circuit if said other measured measurement point (V_{DDi}, t_{PDi}) is outside said range.

9. The semiconductor evaluation method according to claim 8, further comprising the step of
estimating values of said total wiring delay time t_{PWD} already measured by said test section or said measurement section as the total wiring delay time of a longest signal delay path, a gate delay time t_{PGD} already measured by said test section or said measurement section as the gate delay time of a gate as well as said threshold voltage V_{TH} and said coefficient α which have already been measured by said test section or said measurement section as respectively the threshold voltage and coefficient of a transistor serving as said gate from all data (V_{DD}, t_{PD}) measured by said the test section or said measurement section if second and subsequent pieces of said measured data (V_{DD}, t_{PD}) are all in said range.

10. The semiconductor evaluation method according to claim 9 wherein said coefficients estimated by the coefficient estimation step are used as a basis for producing a result of determination as to whether said first integrated circuit is good or defective or whether said second integrated circuit is good or defective.

11. A semiconductor evaluation program to be executed by a computer for carrying out semiconductor evaluation processing by making use of
a first integrated circuit to be determined as a good or defective circuit in accordance with a combination of a power-supply voltage V_{DD} and a clock frequency,
a second integrated circuit serving as a source for providing information on an operation speed varying in accordance with said power-supply voltage V_{DD},
a test section for producing at least two sets of (V_{DD}, t_{PD}) where notation V_{DD} denotes a specific power-supply voltage V_{DD} peculiar to said first integrated circuit whereas notation t_{PD} denotes a clock period t_{PD} which is the reciprocal of a maximum clock frequency giving a determination result indicating that said first integrated circuit is a good circuit at said specific power-supply voltage V_{DD}, and
a measurement section for producing at least two sets of (V_{DD}, t_{PD}) where notation V_{DD} denotes a particular power-supply voltage V_{DD} peculiar to said second integrated circuit whereas notation t_{PD} denotes a clock period t_{PD} obtained as a result of converting said operation speed obtained at said particular power-supply voltage V_{DD},
wherein semiconductor evaluation processing comprises the steps of:
computing a clock period t_{PD} at any arbitrary power-supply voltage V_{DD} from first data (V_{DD1}, t_{PD1}) already produced by said test section or said measurement section, a threshold voltage V_{TH} and a coefficient α, which have already been produced by said test section or said measurement section as respectively the threshold voltage and coefficient of a given transistor, as well as a total wiring delay time t_{PWD} already produced by said test section or said measurement section;
providing best and worst cases of said first data (V_{DD1}, t_{PD1}), said threshold voltage V_{TH} and said coefficient α, which have already been produced by said test section or said measurement section;
comparing a range having the minimum value of said computed clock periods t_{PD} as its lower limit and the maximum value of said computed clock periods t_{PD} as its upper limit with another measured measurement point (V_{DDi}, t_{PDi}); and
confirming the existence of a defect in said first integrated circuit if said other measured measurement point (V_{DDi}, t_{PDi}) is outside said range.

12. The semiconductor evaluation program according to claim 11, wherein said semiconductor evaluation processing further comprises the step of
estimating values of said total wiring delay time t_{PWD} already measured by said test section or said measurement section as the total wiring delay time of a longest signal delay path, a gate delay time t_{PGD} already measured by said test section or said measurement section as the gate delay time of a gate as well as said threshold voltage _{VTH} and said coefficient α which have already been measured by said test section or said measurement section as respectively the threshold voltage and coefficient of a transistor serving as said gate from all data (V_{DD}, t_{PD}) measured by said the test section or said measurement section if second and subsequent pieces of said measured data (V_{DD}, t_{PD}) are all in said range.

13. The semiconductor evaluation program according to claim 12 wherein said estimated coefficients estimated by the coefficient estimation step are used as a basis for producing a result of determination as to whether said first integrated circuit is good or defective or whether said second integrated circuit is good or defective.
